(19) United States
(12) Patent Application Publication
(10) Pub. No.: US 2015/0232331 A1
(43) Pub. Date: Aug. 20, 2015

(54) LAYER STRUCTURE FOR A MICROMECHANICAL COMPONENT

(71) Applicant: Robert Bosch GmbH, Stuttgart (DE)

(72) Inventors: Axel GROSSE, Pfullingen (DE); Heiko STAHL, Reutlingen (DE)

(21) Appl. No.: 14/624,130

(22) Filed: Feb. 17, 2015

(30) Foreign Application Priority Data
Feb. 17, 2014 (DE) 10 2014 202 820.5

(51) Int. Cl. B81C 1/00; B81B 7/00

(52) U.S. Cl. CPC B81C 1/00595; B81B 7/0077; B81C 2201/053; B81B 2203/06

(57) ABSTRACT

A layer structure for a micromechanical component, having:
a first layer, which is usable both for an electrical wiring of the component and as electrode of the component; and
a second layer which is resistant to oxide etching and is disposed below the first layer, the second layer being formed essentially in one plane.

### FIELD OF THE INVENTION

The present invention relates to a layer structure for a micromechanical component. The invention also relates to a method for producing a layer structure for a micromechanical component.

### BACKGROUND INFORMATION

Today, micromechanical inertial sensors are produced mainly using surface micromechanics technology. In so doing, in addition to various deposition and etching techniques, as an important manufacturing step, a sacrificial layer of silicon oxide is etched with the aid of gaseous HF-vapor (what is termed vapor phase etching). In this step, the micromechanical structures are released from the base material and made movable by removing the oxide sacrificial layer below the micromechanical structures.

However, all oxides which are present in the component or are exposed are attacked in this process step. In the area of the micromechanical functional structures, this is desired; in the area of bonding pads and also for the electrical connections placed within and outside of the sensor core, this is unwanted, because the connections may be destabilized mechanically by undercutting.

In the related art, the problem of the unwanted undercutting is addressed differently in the area of the bonding pads and of the wiring. In the area of the bonding pads, solutions are known which prevent undercutting during vapor phase etching.

In order to avoid undercutting, United States Published Patent Appln. No. 2012/0107993 describes the use of silicon nitride or silicon-rich Si-nitride as protective layer over the conductor tracks on aluminum bonding pads and on the conductor tracks below a micromechanical functional-layer structure.

German Patent No. 198 20 816 describes the use of polysilicon as protection against undercutting in the area of bonding pads of a micromechanical sensor.

German Published Patent Appln. No. 10 2004 059 911 describes nitride and silicon oxide on conductor tracks in the sensor core for protection against undercutting in a process sequence using silicon sacrificial layer techniques and subsequent brief vapor phase etching.

In addition, U.S. Pat. No. 7,270,868 describes the use of a relatively thick patterned silicon-nitride layer below conductor tracks.

### SUMMARY

An object of the present invention is therefore to provide an improved layer structure for a micromechanical component.

The objective is achieved according to a first aspect with a layer structure for a micromechanical component, having:
a first layer, which is usable both for an electrical wiring of the component and as electrode of the component; and
a second layer which is resistant to oxide etching and is disposed below the first layer, the second layer being formed essentially in one plane.

In this way, it is advantageously possible for the first layer to be usable alternatively both as electrical wiring and as electrode. Because of the fact that the second layer is disposed essentially in one plane, the first layer and the second layer may in each case be applied in a single manufacturing step. Cost-effective manufacture and varied usability of the layer structure according to the present invention are thereby facilitated. Due to the etch-resistant second layer, the first layer is not undercut, and thus upon use as electrode, cannot be destroyed or damaged by a movable micromechanical structure situated above it.

When using the first layer as an electrical conductor track, it may be made considerably narrower than conventional conductor tracks. As a result, wire interconnection routing within the component is considerably more flexible and greatly simplified.

According to a second aspect, the objective is achieved by a method for producing a layer structure for a micromechanical component, having the following steps:
Providing a substrate;
Depositing an oxide layer on the substrate;
Depositing a second layer, resistant to oxide etching, on the oxide layer;
Depositing a first layer;
Doping the first layer;
Patterning the first layer; and
Depositing a further oxide layer on the first layer and on the second layer.

One advantageous further refinement of the layer structure provides for forming the second layer as a silicon-rich Si-nitride layer. Thus, a material is used which is resistant to oxide etching, and in this manner, undercutting of the first layer may effectually be prevented.

A further specific embodiment of the layer structure is characterized in that a thickness of the second layer is between approximately 0.5 μm and approximately 1 μm. A dimensioning of the second layer is thereby carried out with which, on one hand, undercutting of the first layer may reliably be avoided, and with which an additional capacitance on the layer structure is able to be minimized.

A further specific embodiment of the layer structure has the feature that the second layer is formed over the entire surface below the first layer. A time-saving and cost-effective application of the second layer is thus facilitated.

Another specific embodiment of the layer structure is characterized in that the second layer is formed in patterned fashion below the first layer. This variant is advantageous when a full-surface placement of the second layer below the first layer is not possible. In addition, in this way, an effect of mechanical stress on the wafer (wafer bow) may be kept small.

The invention is described in detail in the following with further features and advantages on the basis of several figures. In this context, all features described form the subject matter of the invention, regardless of their portrayal in the specification and in the figures and regardless of their antecedent reference in the patent claims. Identical or functionally equivalent elements have the same reference numerals.

### BRIEF DESCRIPTION OF THE DRAWINGS

FIG. 1a and 1b show two conventional layer structures of a micromechanical component.

FIG. 2 shows two further conventional layer structures of a micromechanical component.

FIG. 3 shows two further conventional layer structures for a micromechanical component.

FIGS. 4a and 4b show two specific embodiments of layer structures according to the present invention for a micromechanical component.

FIG. 5 shows a sequence in principle for one specific embodiment of the method.

FIG. 6 shows a block diagram of a micromechanical component.

### DETAILED DESCRIPTION

Vapor phase etching is understood hereinafter as vapor phase etching using gaseous HF (hydrogen fluoride) gas. This etching process is also known as “sacrificial-layer etching.”

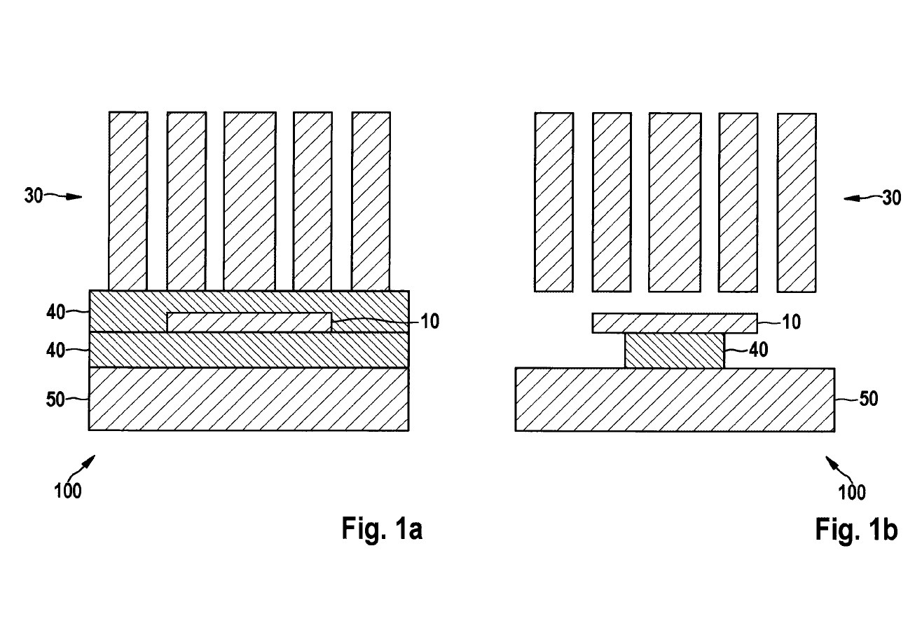

FIG. 1a shows a conventional layer structure 100 for a micromechanical component (not shown) prior to the vapor phase etching indicated. A substrate 50 is discernible, on which an oxide layer 40 (e.g., Si-oxide) is disposed. Situated on oxide layer 40 is a first layer 10 (e.g., made of polysilicon), which acts as an electrical conductor track for the component. A micromechanical, movable functional layer 30 is disposed above first layer 10, a further oxide layer 40 being located between first layer 10 and functional layer 30.

FIG. 1b shows the structure of FIG. 1a after the vapor phase etching. One can see that first layer 10 is partially undercut by the process of the vapor phase etching, so that areas of the conductor track project beyond underlying oxide layer 40. Unfavorable movements of micromechanical functional layer 30, which impact the conductor track, may lead disadvantageously to damage or breakages of the electrical conductor track.

The undercuttings of the conductor tracks necessitate either a very wide routing of the conductor track, so that the conductor track is not completely released from substrate 50, or, in the case of the completely undercut conductor track lying above, may represent very great restrictions for design of the wiring, which must then be self-supporting.

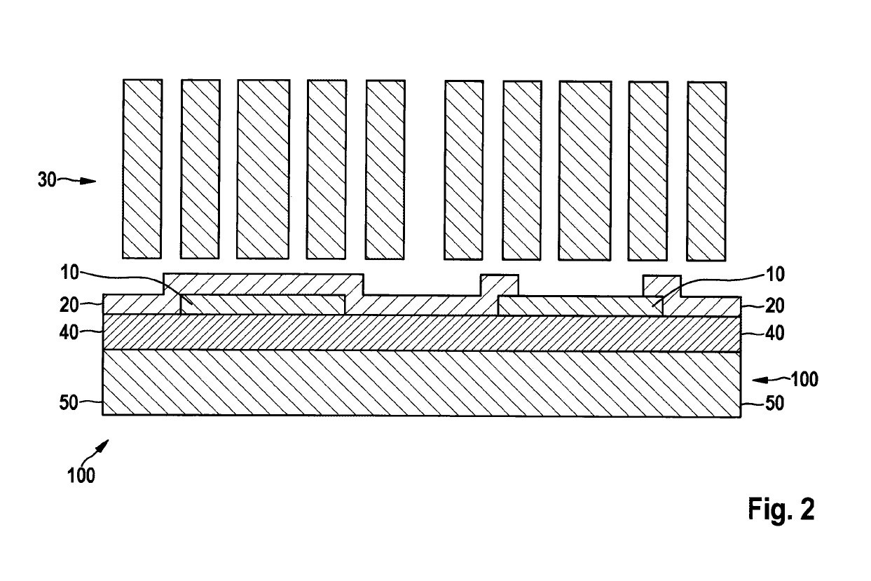

FIG. 2 shows two further conventional layer structures 100. In a left area of FIG. 2, a second layer 20 is discernible that is formed as a protective layer with silicon nitride (Si₃N₄) or silicon-rich Si-nitride above first layer 10 which acts as conductor track. In this case, second layer 20 is disposed on first layer 10 and oxide layer 40.

For the case when first layer 10 is used as an electrode, as shown in the right portion of FIG. 2, second layer 20 must disadvantageously be opened or removed above the electrode. This is technically painstaking and thus costly, and requires an additional etching process for second layer 20. With the movable micromechanical structures disposed above the electrode, changes in capacitance are able to be ascertained with the electrode. For this purpose, as a rule, hollow spaces (not shown), with which capacitive charge changes are determined, exist in the vicinity of the electrode.

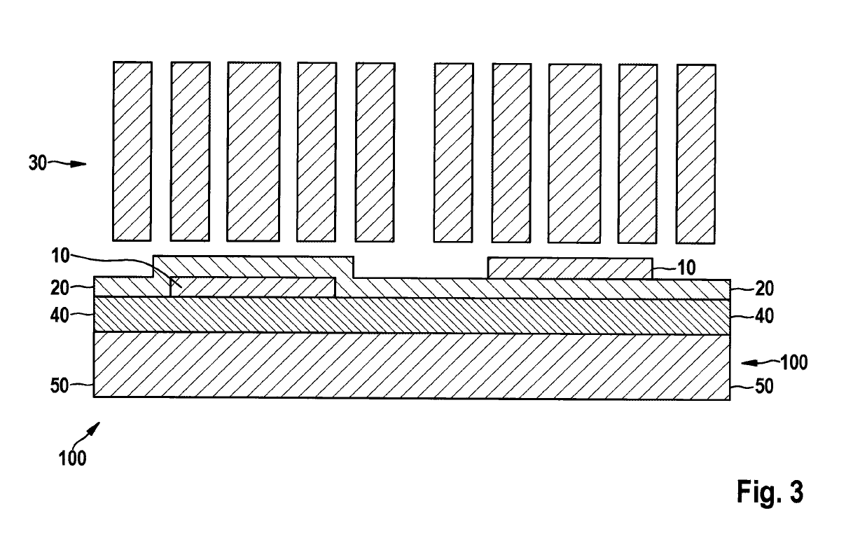

FIG. 3 shows further known layer structures 100 having a second layer 20 for the protection of a first layer 10 acting as conductor track. One can see in the depiction to the left in FIG. 3 that second layer 20 is disposed exclusively above first layer 10 acting as electrical conductor track.

In further known layer structure 100 shown in the right portion of FIG. 3, it is discernible that first layer 10 is used as an electrode, in this case second layer 20 being disposed completely below the electrode.

The indicated uses of first layer 10 as electrical conductor track and as electrode, respectively, are realized in a manner that first of all, first layer 10 acting as conductor track is applied or deposited by evaporation on oxide layer 40. In a next manufacturing step, second layer 20 is deposited, and in a further manufacturing step, another first layer 10 acting as electrode is deposited on second layer 20. A corresponding manufacturing process for the structure of FIG. 3 is therefore painstaking and cost-intensive. As a result, therefore, given a formation of first layer 10 as conductor track and as electrode, second layer 20 is disposed in different planes.

In the event the conductor tracks are covered with silicon nitride or silicon-rich Si-nitride, it must be taken into consideration that silicon nitride is able to capture and store high electrical charge densities, that is, that as a rule, the silicon-nitride protective layers over the conductor tracks are highly electrically charged. If the intention is to also use a conductor track of this nature lying below as an active electrode, for example, in the case of Z-sensors, second layer 20 above the electrode must be removed, because the electrical charges of second layer 20 would interfere with the operation of the electrode.

As a result, two separate deposition steps of first layer 10 are necessary for the formation of the structures of FIG. 3 for the functionalities of conductor track and electrode.

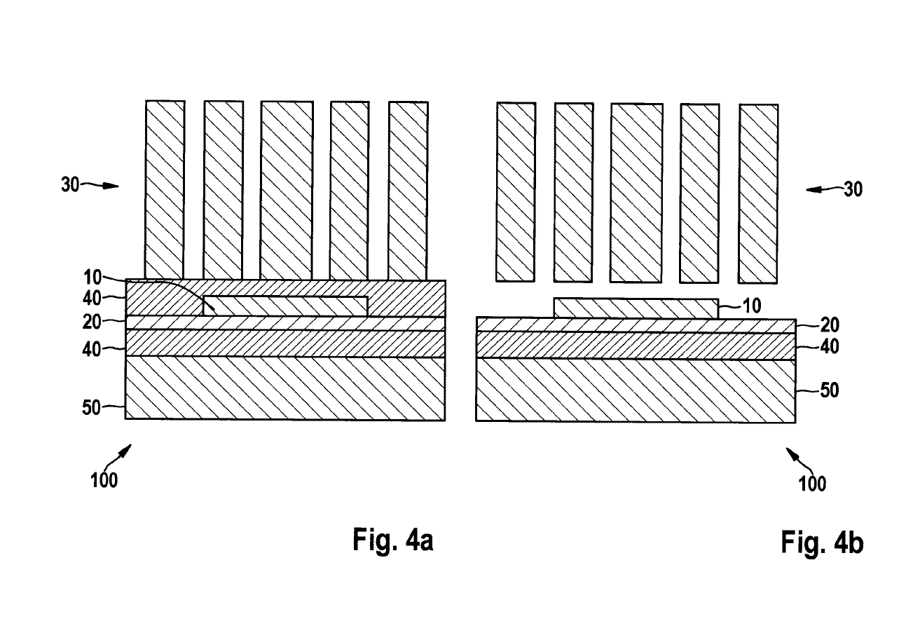

According to the present invention, a thin (layer thickness approximately 0.5 μm approximately 1 μm) second layer 20 of silicon-rich Si-nitride is disposed below conductor-track plane 10, as shown in FIG. 4a and FIG. 4b. In contrast to stoichiometric silicon nitride Si₃N₄, silicon-rich Si-nitride has a high silicon content (preferably equal to many parts of Si and nitride, e.g., in the form of Si₄N₄), and depending on the silicon content, exhibits very high selectivity in an HF vapor-phase etching process compared to Si-oxide. Qualitatively well-producible compositions of silicon-rich Si-nitride exhibit a selectivity of approximately 30:1. A silicon-rich nitride layer having a thickness of approximately 0.5 μm is sufficient in the case of a targeted etching of, on average, approximately 15 μm silicon oxide. Taking etching-rate fluctuations and layer-thickness tolerances and composition tolerances into account, a silicon-nitride layer thickness of approximately 1 μm is advantageously provided. This layer is electrically insulating, and therefore advantageously does not need to be patterned separately.

FIG. 4a shows a specific embodiment of a layer structure 100 with use of first layer 10 as an electrical conductor track, an oxide layer 40 being disposed on the upper side of the conductor track, and second layer 20, having silicon-rich silicon nitride and being resistant to oxide etching, being disposed below the conductor track. Layer structure 100 also includes an oxide layer 40 as insulating layer with respect to underlying substrate 50, as well as possibly further oxide and silicon layers (not shown) for the construction of micromechanical functional layer 30.

FIG. 4b shows the specific embodiment of layer structure 100 according to the present invention in the case of a use of first layer 10 as an electrode, where starting from the structure of FIG. 4a, oxide layer 40 on the upper side of first layer 10 is removed by vapor phase etching, thereby realizing a free access to micromechanical functional layer 30 situated above. Thin second layer 20 is used as a protective layer for protection against unwanted undercutting during the vapor phase etching process. Since second layer 20 is resistant to the indicated vapor phase etching, it is not attacked by the HF-etching gas and remains essentially unaffected.

Thus, it is discernible from FIGS. 4a and 4b that the functionalities of first layer 10 as conductor track and as electrode are able to be realized in an easy manner with the aid of second layer 20 which is disposed under first layer 10.

Because of the fact that second layer 20 is not situated upon, but rather completely below first layer 10, it does not have to be patterned separately when, for example, electrical contacts (not shown) are necessary for micromechanical functional layer 30. Second layer 20 also does not have to be removed from areas of first layer 10 which are intended to be used as electrodes. In producing an electrical substrate contact, second layer 20 may be patterned with the same mask as underlying oxide layer 40, in doing which, only another etching process then having to be provided which also etches Si-nitride (e.g., plasma etching).

Advantageously, parasitic capacitances are not or are scarcely increased by the formation of thin second layer 20 below first layer 10. To be sure, second layer 20 makes an additional contribution to the parasitic capacitance with respect to substrate 50, since it represents a further dielectric layer. At the same time, however, the additional layer thickness produced by second layer 20 more than compensates for even the increased dielectric constant, so that the parasitic capacitance drops from approximately 0.014 fF/μm² to approximately 0.012 fF/_{μm}².

Above all, however, by preventing the undercutting of first layer 10, the electrical conductor tracks may advantageously be made substantially narrower (e.g., approximately 5 μm instead of approximately 40 μm wide), an electrical conductor-track resistance being able to be dimensioned correspondingly. As a result, parasitic capacitances may even be advantageously reduced.

In this manner, considerable simplification and increase of flexibility in design are obtained for many micromechanical sensors having complex wiring (e.g., yaw-rate sensors). In addition, because second layer 20 is disposed over the entire surface below first layer 10, no additional topography results which could interfere with the subsequent process flow.

Second layer 20 is preferably selective in such a way that it is not attacked during a sacrificial-layer or vapor-phase etching process, but rather only oxide layer 40 situated between micromechanical functional layer 30 and first layer 10.

As a result, the present invention permits a simple multifunctional use of the polysilicon of first layer 10 as electrical conductor track and as electrode. In this way, separation of the functionalities of first layer 10 into “conductor track” and “electrode” is advantageously avoided in an easy manner. Cost-effective and efficient manufacturing processes may thus be realized.

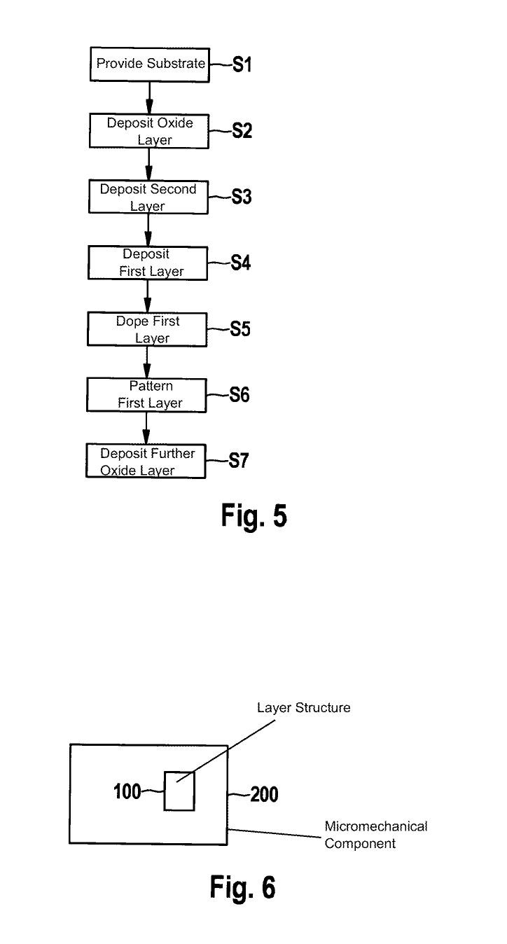

FIG. 5 shows a sequence of the method in principle:

In a first step S1, a substrate 50 is provided.

In a second step S2, an insulating oxide layer is deposited with a layer thickness of approximately 2.5 μm on substrate 50, the insulating oxide layer providing an electrical insulation for substrate 50 and keeping parasitic capacitances with respect to substrate 50 low.

At this point, in a further step S3, second layer 20 in the form of silicon-rich Si-nitride is deposited on oxide layer 40.

In a further step S4, first layer 10 having polysilicon is deposited (e.g., with approximately 0.45 μm layer thickness) onto the full-surface layer stack made of oxide and silicon-rich nitride, and in a fifth step and a sixth step S5, S6, is doped and patterned with the aid of lithography.

In a seventh step S7, a further oxide layer 40 is deposited onto first layer 10 and onto second layer 20.

As a result, a structure according to FIG. 4a is available which, in an easy manner, permits use of first layer 10 as electrode and as conductor track.

In subsequent process steps, if desired, a substrate contact (not shown) may be created by etching a contact to substrate 50 through all oxide layers 40 (insulating oxide and sacrificial oxides). In this etching, embedded second layer 20 must also then be patterned at the same time. Advantageously, this requires no new mask, but rather only an adaptation of the etching program.

If the full-surface deposition of the entire sensor below first layer 10 with second layer 20 is not desired (e.g., because of wafer bending which is produced by the layer stress of the silicon-rich nitride), second layer 20 may be obtained with an additional masking level with etching of second layer 20 only in the area of the sensor core; it may be removed again in the area of the bonding frame and of the bonding pads, as a rule no undercutting taking place there in any case during the vapor-phase etching process.

FIG. 6 shows a block diagram of a micromechanical component 200 having a layer structure 100 according to the present invention.

In summary, the present invention provides a cost-effective solution for avoiding undercutting of underlying conductor tracks, which does not hinder use of the conductor tracks as electrode. A layer structure is proposed with which, with little expenditure, it is possible to realize different functionalities of a polysilicon layer. For example, using the polysilicon layer, because there is no undercutting, electrical conductor tracks may advantageously be made very narrow, which substantially increases freedom in designing the routing of the conductor tracks. In particular, this aspect is advantageous when complexity of wiring levels in sensors is very high. In addition, the first layer may advantageously be utilized easily as electrode.

Although the present invention has been described on the basis of specific exemplary embodiments, it is by no means limited to them. One skilled in the art will thus alter the features described or combine them with one another without departing from the essence of the invention.

What is claimed is:

1. A layer structure for a micromechanical component, comprising:
a first layer, which is usable both for an electrical wiring of the component and as electrode of the component; and
a second layer which is resistant to oxide etching and is disposed below the first layer, the second layer being formed essentially in one plane.

2. The layer structure as recited in claim 1, wherein the second layer is in the form of a silicon-rich Si-nitride layer.

3. The layer structure as recited in claim 1, wherein a thickness of the second layer is between approximately 0.5 μm and approximately 1 μm.

4. The layer structure as recited in claim 1, wherein the second layer is formed essentially over an entire surface below the first layer.

5. The layer structure as recited in claim 1, wherein the second layer is formed in patterned fashion below the first layer.

6. A micromechanical component, comprising:
a layer structure that includes:
a first layer, which is usable both for an electrical wiring of the component and as electrode of the component, and
a second layer which is resistant to oxide etching and is disposed below the first layer, the second layer being formed essentially in one plane; and
at least one micromechanically movable functional layer disposed above the layer structure.

7. A method for producing a layer structure for a micromechanical component, comprising:
providing a substrate;
depositing an oxide layer on the substrate;
depositing a second layer, resistant to oxide etching, on the oxide layer;
depositing a first layer;
doping the first layer;
patterning the first layer; and
depositing a further oxide layer on the first layer and on the second layer.

8. A method of using a layer structure that includes a first layer, which is usable both for an electrical wiring of the component and as an electrode of the component, and a second layer which is resistant to oxide etching and is disposed below the first layer, the second layer being formed essentially in one plane, the method comprising using the first layer alternatively as the electrical wiring or as the electrode.
